(19) United States
(12) Patent Application Publication
(10) Pub. No.: US 2014/0167163 A1
(43) Pub. Date: Jun. 19, 2014

(54) Multi-Fin FinFETs with Epitaxially-Grown Merged Source/Drains

(71) Applicant: INTERNATIONAL BUSINESS MACHINES CORP, Armonk, NY (US)

(72) Inventors: Kangguo Cheng, Schenectady, NY (US); Ali Khakifirooz, Mountain View, CA (US); Alexander Reznicek, Troy, NY (US); Raghavasimhan Sreenivasan, Schenectady, NY (US); Thomas N. Adam, Slingerlands, NY (US)

(73) Assignee: INTERNATIONAL BUSINESS MACHINES CORPORATION, Armonk, NY (US)

(21) Appl. No.: 13/716,646

(22) Filed: Dec. 17, 2012

(51) Int. Cl. H01L 29/78; H01L 29/66

(52) U.S. Cl. CPC H01L 29/78; H01L 29/66477
USPC 257/347; 438/151

(57) ABSTRACT

Embodiments include multi-fin finFET structures with epitaxially-grown merged source/drains and methods of forming the same. Embodiments may include an epitaxial insulator layer above a base substrate, a gate structure above the epitaxial insulator layer, a semiconductor fin below the gate structure, and an epitaxial source/drain region grown on the epitaxial insulator layer adjacent to an end of the semiconductor fin. The epitaxial insulator layer may be made of an epitaxial rare earth oxide material grown on a base semiconductor substrate. Embodiments may further include fin extension regions on the end of the semiconductor fin between the end of the end of the semiconductor fin and the epitaxial source/drain region. In some embodiments, the end of the semiconductor fin may be recessed below the gate structure.

### BACKGROUND

The present invention generally relates to semiconductor devices, and particularly to the manufacture of epitaxially-grown merged source/drains of multi-fin finFETs.

Fin field effect transistors (finFET) are an emerging technology which provides solutions to field effect transistor (FET) scaling problems at, and below, the 22 nm node. FinFET structures include at least one narrow semiconductor fin gated on at least two sides of each of the at least one semiconductor fin. FinFET structures may be formed on a semiconductor-on-insulator (SOI) substrate, because of the low source/drain diffusion, low substrate capacitance, and ease of electrical isolation by shallow trench isolation structures.

FinFET devices having multiple fins covered by a single gate have been developed to increase the surface area contact between the channel region of the fins and the gate. The multiple fins may be merged on one end to form a single source/drain region. Merging the multiple fins may be accomplished by epitaxially growing source/drain material, such as silicon, on the fin surface. However, as semiconductor devices continue to decrease in size, the smaller spaces between the fins may lead to issues such as faceting when growing merged source/drain regions. Due to the nature of epitaxial growth and certain structural features of integrated circuit devices, faceting is the result of epitaxially grown regions exhibiting undesirably formed shapes that impact device performance and reliability. In the case of forming source/drain regions on SOI finFETs, epitaxial growth occurs primarily on the fin sidewalls. Sidewall growth can result in faceting, voids, and other defects where growths on opposing sidewalls meet. Therefore, a method of growing source/drain regions of multigate devices that may, among other things, avoid faceting is desirable.

### BRIEF SUMMARY

The present invention relates to multi-fin fin field effect transistors (finFETs) having epitaxially-grown merged source/drain regions. According to at least one exemplary embodiment, a semiconductor structure may include an epitaxial insulator layer above a base substrate, a gate structure above the epitaxial insulator layer, a semiconductor fin below the gate structure with an exposed end, and an epitaxial source/drain region on the epitaxial insulator layer adjacent to the end of the semiconductor fin.

According to another embodiment of the invention, a method of forming a semiconductor structure may include forming a semiconductor fin on an epitaxial insulator layer, forming a gate structure including a gate electrode and a spacer on a sidewall of the gate electrode over the semiconductor fin that divides the semiconductor fin into a body portion covered by the gate structure and a end portion not covered by the gate structure, removing the end portion of the semiconductor fin, and forming an epitaxial source/drain region on the epitaxial insulator layer and in contact with the body portion of the semiconductor fin

Another embodiment of the invention may include a design structure tangibly embodied in a machine readable medium for designing, manufacturing, or testing an integrated circuit including an epitaxial insulator layer above a base substrate, a gate structure above the epitaxial insulator layer, a semiconductor fin below the gate structure with an exposed end, and an epitaxial source/drain region on the epitaxial insulator layer adjacent to the end of the semiconductor fin.

### BRIEF DESCRIPTION OF THE SEVERAL VIEWS OF THE DRAWINGS

FIG. 1 depicts a semiconductor-on-insulator (SOI) substrate including a epitaxial insulator layer, according to an embodiment of the present invention.

FIG. 2 depicts forming fins on the epitaxial insulator layer of the SOI substrate, according to an embodiment of the present invention.

FIG. 3 depicts forming a gate structure and spacers over body portions of the fins, according to an embodiment of the present invention.

FIG. 4 depicts removing end portions of the fins from outside the gate structure and the spacers, according to an embodiment of the present invention.

FIG. 5 depicts thinning the epitaxial insulator layer outside the gate structure and the spacers, according to an embodiment of the present invention.

FIG. 6 depicts forming source/drain regions in contact with the ends of the fins on the epitaxial insulator layer of FIG. 5, according to an embodiment of the present invention.

FIG. 7 depicts forming fin extension regions on the ends of the fins of FIG. 5, according to an embodiment of the present invention.

FIG. 8 depicts forming source/drain regions in contact with the fin extension regions on the epitaxial insulator layer of FIG. 7, according to an embodiment of the present invention.

FIG. 9 depicts recessing the ends of the fins of the FIG. 5, according to an embodiment of the present invention.

FIG. 10 depicts forming source/drain regions in contact with the ends of the fins on the epitaxial insulator layer of FIG. 9, according to an embodiment of the present invention.

FIG. 11 depicts recessing the ends of the fins of the FIG. 5, according to an embodiment of the present invention.

FIG. 12 depicts forming fin extension regions on the ends of the fins of FIG. 11, according to an embodiment of the present invention.

FIG. 13 depicts forming source/drain regions in contact with the fin extension regions on the epitaxial insulator layer of FIG. 12, according to an embodiment of the present invention.

FIG. 14 is a flow diagram of a design process used in semiconductor design, manufacture, and/or test according to an embodiment of the present invention.

Elements of the figures are not necessarily to scale and are not intended to portray specific parameters of the invention. For clarity and ease of illustration, dimensions of elements may be exaggerated. The detailed description should be consulted for accurate dimensions. The drawings are intended to depict only typical embodiments of the invention, and therefore should not be considered as limiting the scope of the invention. In the drawings, like numbering represents like elements.

### DETAILED DESCRIPTION

Exemplary embodiments now will be described more fully herein with reference to the accompanying drawings, in which exemplary embodiments are shown. This disclosure may, however, be embodied in many different forms and should not be construed as limited to the exemplary embodiments set forth herein. Rather, these exemplary embodiments are provided so that this disclosure will be thorough and complete and will fully convey the scope of this disclosure to those skilled in the art. In the description, details of well-known features and techniques may be omitted to avoid unnecessarily obscuring the presented embodiments.

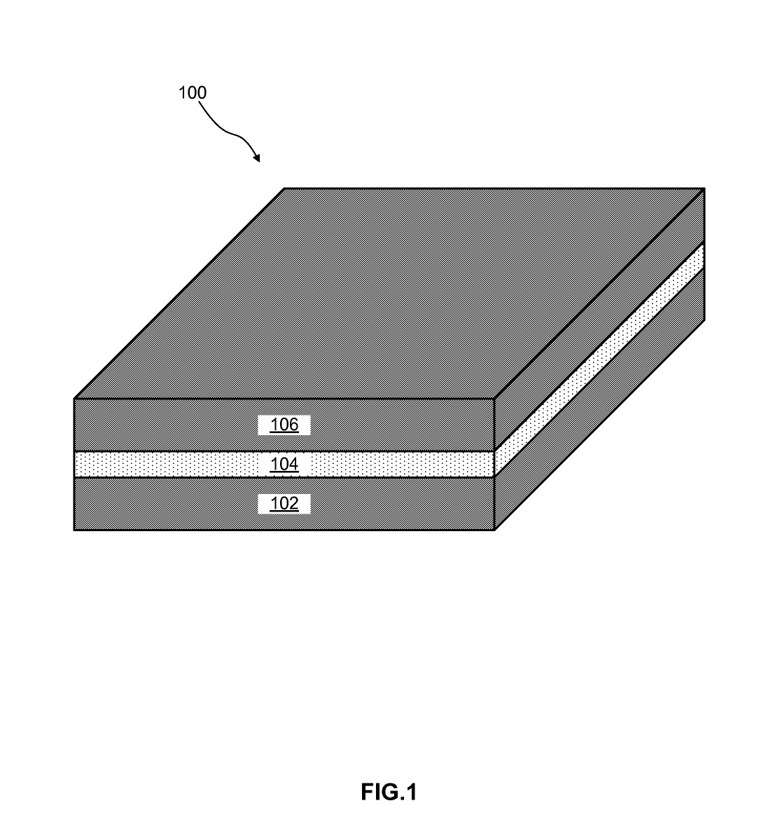

FIGS. 1-13 depict methods of forming exemplary multi-fin fin field effect transistor (finFET) structures with substantially defect-free merged source/drain regions formed on a semiconductor-on-insulator (SOI) substrate with an epitaxially grown buried insulator layer.

Referring to FIG. 1, an SOI substrate 100 may include a base substrate 102, an epitaxial insulator layer 104, and an epitaxial SOI layer 106. The epitaxial insulator layer 104 may isolate the epitaxial SOI layer 106 from the base substrate 102. The base substrate 102 may be made from any of several known semiconductor materials such as, for example, silicon, germanium, silicon-germanium alloy, silicon carbide, silicon-germanium carbide alloy, and compound (e.g. III-V and II-VI) semiconductor materials. Non-limiting examples of compound semiconductor materials include gallium arsenide, indium arsenide, and indium phosphide. Typically the base substrate 102 may be about, but is not limited to, several hundred microns thick. For example, the base substrate 102 may include a thickness ranging from 0.5 mm to about 1.5 mm.

The epitaxial insulator layer 104 may be formed by growing an epitaxial insulator material on the base substrate 102. The epitaxial insulator layer 104 may be made, for example, of any known insulator capable of forming an epitaxial layer on base substrate 102 and supporting epitaxial growth of the epitaxial SOI layer, including, for example, rare-earth oxides such as scandium oxide (Sc₂O₃) cadmium oxide (Cd₂O₃), yttrium oxide (Y₂O₃), scandium oxide (Sc₂O₃), lanthanum oxide (La₂O₃), praseodymium oxide (Pr₂O₃), thorium oxide (ThO₂), actinium oxide (Ac₂O₃), Gadolinium Oxide (Gd₂O₃), Strontium Titanate (SrTiO₃), and Barium Titanate (BaTiO₃), and may have a thickness of approximately 10 nm to approximately 500 nm. In one embodiment, the epitaxial insulator layer may have a thickness of approximately 150 nm. By replacing the amorphous buried insulator layer of a typical SOI substrate with the epitaxial insulator layer 104, the SOI substrate 100 may provide the necessary isolation required of an SOI substrate while also providing a buried insulator layer capable of supporting later epitaxial growth.

The SOI layer 106 may be made of any of the several semiconductor materials possible for the base substrate 102 capable of being forming epitaxial layers on the epitaxial insulator layer 104. In general, the base substrate 102 and the SOI substrate layer 104 may include either identical or different semiconducting materials with respect to chemical composition, dopant concentration and crystallographic orientation. The SOI layer 106 may be doped with p-type dopants such as boron or doped with n-type dopants such as phosphorus and/or arsenic. The dopant concentration may range from approximately 1×10¹⁵ cm⁻³ to approximately 1×10¹⁹ cm⁻³, preferably approximately 1×10¹⁵ cm⁻³ to approximately 1×10¹⁶ cm⁻³. In one embodiment, the SOI layer is undoped. The SOI layer 106 may be approximately 5 nm to approximately 300 nm thick, preferably approximately 30 nm.

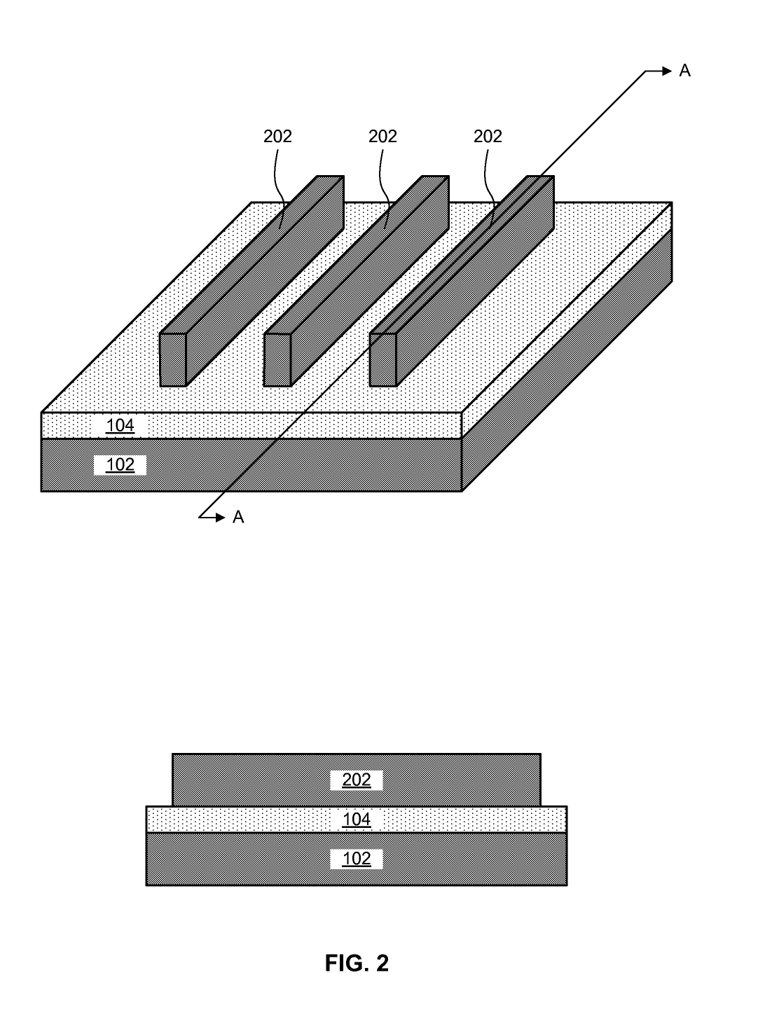

Referring to FIG. 2, fins 202 may be formed by removing material from the SOI layer 106 (FIG. 1), for example by a photolithography process followed by an anisotropic etching process such as reactive ion etching (RIE) or plasma etching. The fins 202 may have a width of approximately 2 nm to approximately 100 nm, preferably approximately 4 nm to 40 approximately nm. In a preferred embodiment, the fins 202 may have a width in the range of approximately 6-15 nm. The fins 202 may have a height of approximately 5 nm to approximately 300 nm, preferably approximately 10 nm to approximately 80 nm. In a preferred embodiment, fin 202 may be fabricated to include a height in the range of approximately 20 nm to approximately 40 nm. In some embodiments, a hard mask layer (not shown) may be incorporated into the etching process to protect the fins 202 during their formation, and also during subsequent processing steps. While the depicted embodiment includes three fins, it will be understood that other embodiments may include one or more fins. FIGS. 2-13 each include an isometric view of the relevant structure and a cross section view along line A-A′. Each cross section view depicted in the FIGS. 2-13 represents a view perpendicular to the length of one of the fins 202.

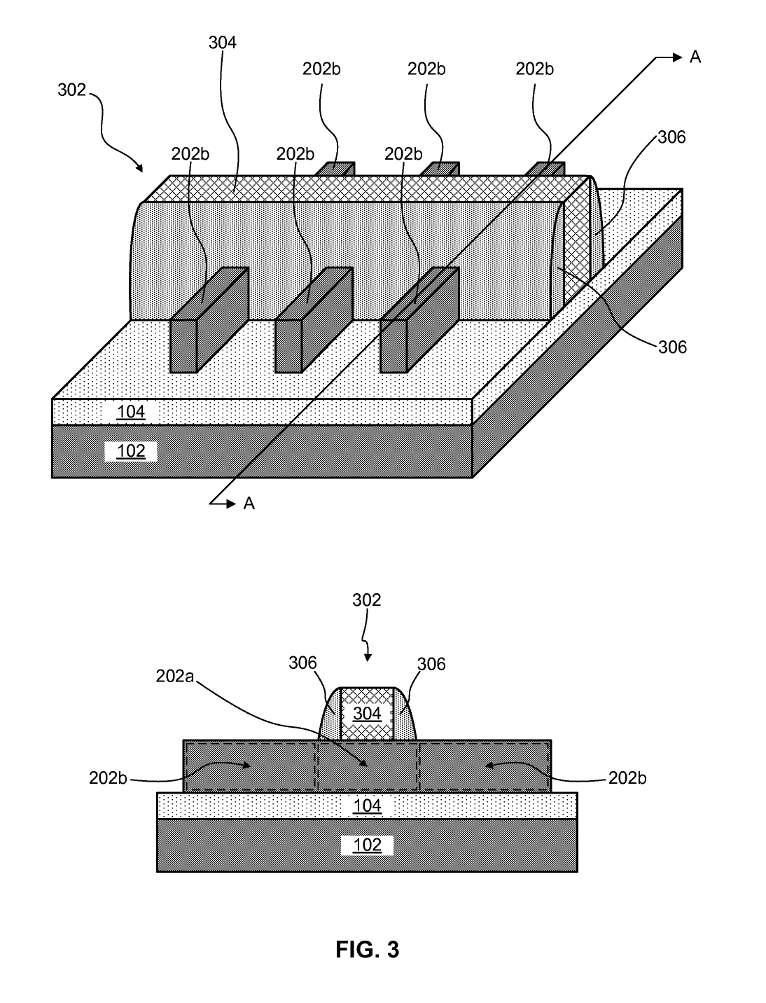

Referring to FIG. 3, a gate structure 302 is formed over middle portions of the fins. The gate structure 302 may include a gate 304 and spacers 306. The gate 304 may include a gate dielectric and a gate conductor that can be formed via any known process in the art, including a gate-first process and a gate-last process. The gate structure may have a height of approximately 40 nm to approximately 200 nm, preferably approximately 50 nm to approximately 150 nm.

In a gate-first process, the gate 304 may include a gate dielectric, a gate electrode and a hard cap to protect the gate electrode and the gate dielectric (not shown). The gate dielectric may include an insulating material including, but not limited to: oxide, nitride, oxynitride or silicate including metal silicates and nitrided metal silicates. In one embodiment, the gate dielectric may include an oxide such as, for example, SiO₂, HfO₂, ZrO₂, Al₂O₃, TiO₂, La₂O₃, SrTiO₃, LaAlO₃, and mixtures thereof. The physical thickness of the gate dielectric may vary, but typically may have a thickness ranging from approximately 0.5 nm to approximately 10 nm. The gate electrode may be formed on top of the gate dielectric. The gate electrode may be deposited by any suitable technique known in the art, for example by atomic layer deposition (ALD), chemical vapor deposition (CVD), physical vapor deposition (PVD), molecular beam deposition (MBD), pulsed laser deposition (PLD), or liquid source misted chemical deposition (LSMCD). The gate electrode may include, for example, Zr, W, Ta, Hf, Ti, Al, Ru, Pa, metal oxides, metal carbides, metal nitrides, transition metal aluminides (e.g. Ti₃Al, ZrAl), TaC, TiC, TaMgC, or any combination of those materials. The gate electrode may also include a silicon layer located on top of a metal material, whereby the top of the silicon layer may be silicided. The gate electrode may have a thickness approximately of approximately 20 nm to approximately 100 nm and a width of approximately 10 nm to approximately 250 nm, although lesser and greater thicknesses and lengths may also be contemplated. The hard cap may be made of an insulating material, such as, for example, silicon nitride, capable of protecting the gate electrode and gate dielectric during subsequent processing steps.

In a gate-last process, the gate 304 may include a sacrificial gate (not shown) that may be later removed and replaced by a gate dielectric and a gate electrode such as those of the gate-first process described above. The sacrificial gate may be made of a polysilicon material with a sacrificial dielectric material (e.g., silicon oxide) formed using known deposition techniques known in the art. The gate structure may also include a hard cap (not shown) made of an insulating material, such as, for example, silicon nitride, capable of protecting the gate electrode and gate dielectric during subsequent processing steps.

Following formation of the gate 304, spacers 306 may be formed on sidewalls of the gate 304. The spacers 306 may be made of, for example, silicon nitride, silicon oxide, silicon oxynitrides, or a combination thereof, and may be formed by any method known in the art, including depositing a conformal silicon nitride layer over the gate 304 and etching to remove unwanted material from the conformal silicon nitride layer. The spacers 306 may have a thickness of approximately 1 nm to approximately 10 nm. In some embodiments, the spacers 306 may have a thickness of approximately 1 nm to approximately 5 nm. Formation of the gate structure 302 divides the fins 202 into fin body portions 202a covered by the gate structure 302, and fin end portions 202b not covered the gate structure 302.

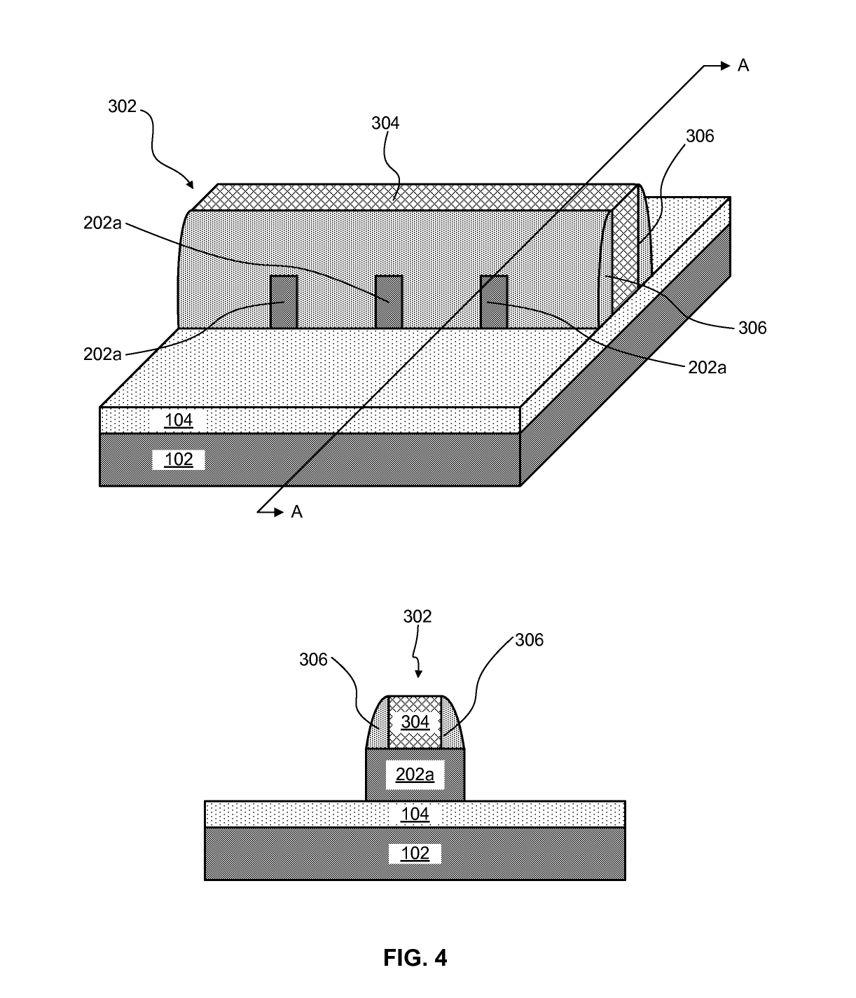

Referring to FIG. 4, the fin end portions 202b may be removed using a known anisotropic etching process, such as, for example, reactive ion etching (RIE) or plasma etching. The etching process may be selective so that it may remove the fin end portions 202b without substantially impacting the surrounding structures, including the epitaxial insulator layer 104, the fin body portions 202a, the gate electrode 304, and the spacers 306. By removing the fin end portions 202, ends of the fin body portions 202a may be exposed. Following removal of the fin end portions 202b, extension implants may be possible to add dopants to the fin body portions 202a. Possible dopants may include boron, in the case of pFETs, and arsenic or phosphorus, in the case of nFETs.

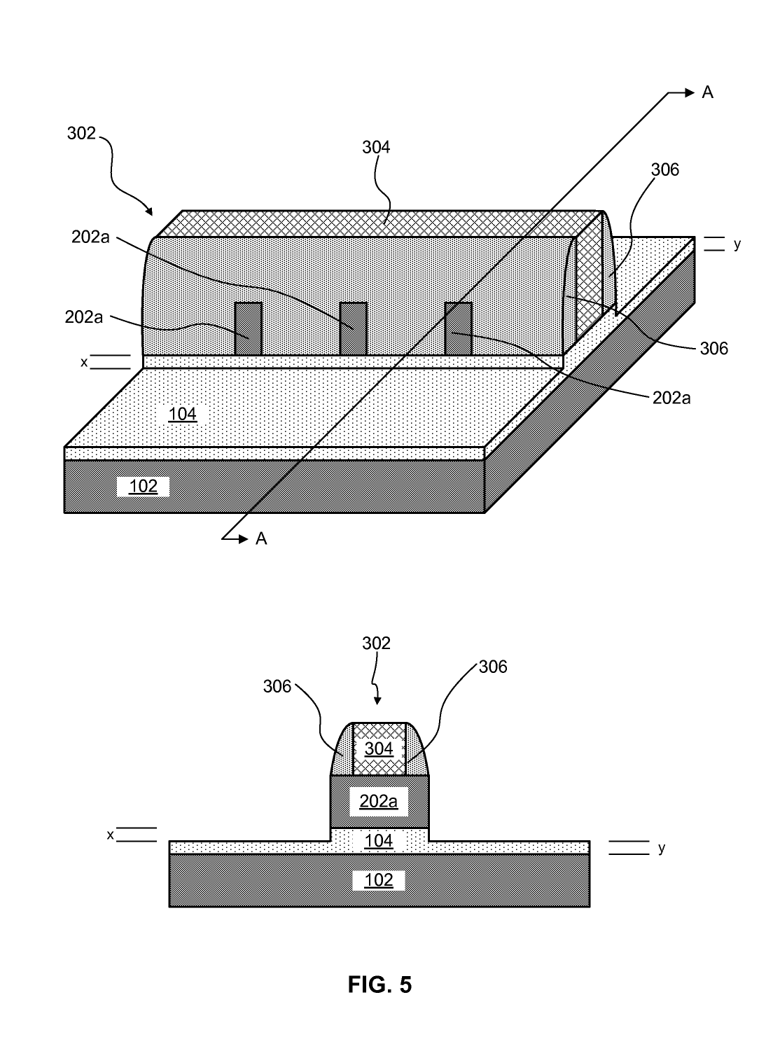

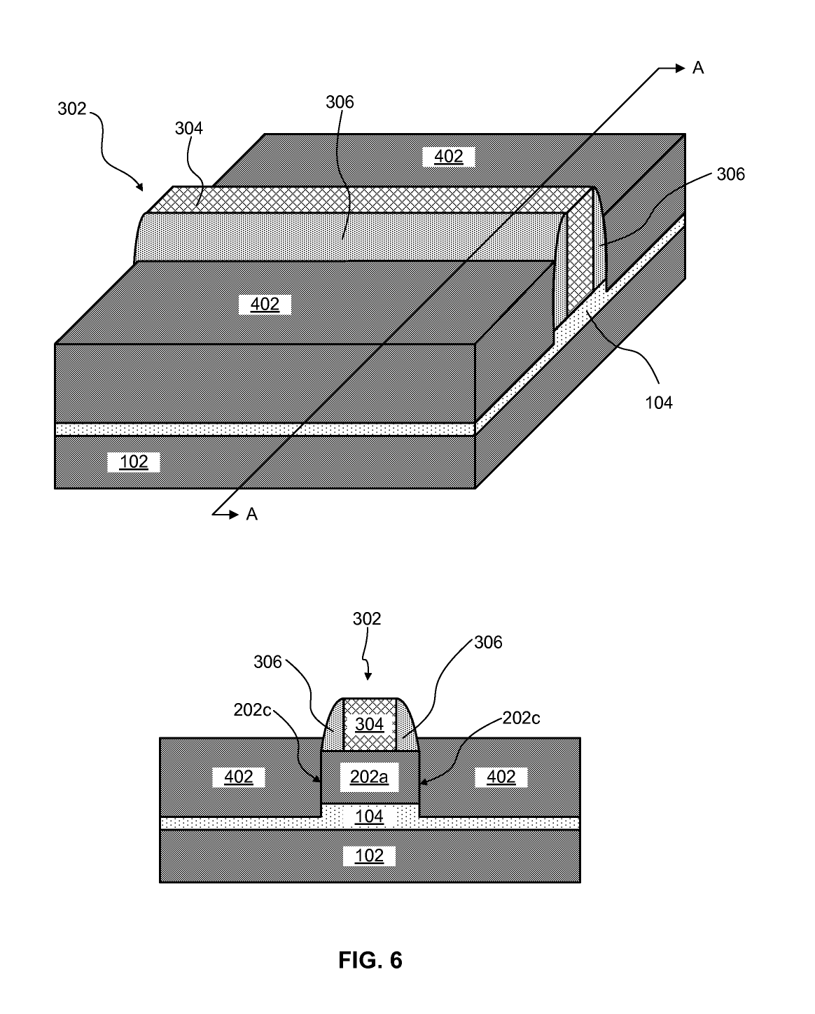

Referring to FIG. 5, the epitaxial insulator layer 104 may be optionally thinned in areas beyond the gate structure 302 using a known anisotropic etching process, such as, for example, RIE or plasma etching. In some embodiments, the epitaxial insulator layer 104 may be recessed by a depth of x, where x may vary from approximately 0 nm to approximately 150 nm, preferably approximately 20 nm to approximately 50 nm. In some embodiments, the thinned region of epitaxial insulator layer 104 may have a thickness y of not less than approximately 5 nm or 5% of the initial thickness of the epitaxial insulator layer 104, whichever is greater. The etching process may be selective so that it may thin the epitaxial insulator layer 104 without substantially impacting the surrounding structures, including the fin body portions 202a, the gate electrode 304, and the spacers 306. Extension implants may also occur after thinning the epitaxial insulator layer. While optional, thinning the epitaxial insulator layer 104 may allow for the source/drain regions 402 formed in FIG. 6 to have a greater total volume. In embodiments where the source/drain regions may be used to apply stress to the channel region of the FET (i.e., the region of fin body portion 202a beneath the gate electrode 304), a greater total source/drain volume may allow for a greater amount of stress to be applied.

Referring to FIG. 6, epitaxial source/drain regions 402 may be formed adjacent to the gate structure 302 and in contact with fin body portions 202a by selectively growing an epitaxial semiconductor layer on the epitaxial insulator layer 104. Depending on the type of FET device being formed (i.e., pFET or nFET), the epitaxial source/drain regions may be made of silicon, a silicon-germanium alloy, or carbon doped silicon.

For example, for a pFET, the epitaxially grown source/drain region 402 may be made of silicon or a silicon germanium-alloy, where the atomic concentration of germanium may range from about approximately 10% to approximately 80%, preferably from approximately 20% to approximately 60%. By including germanium in the source/drain regions 402, the source/drain regions 402 may apply compressive stress to the epitaxial insulator layer 104 due to the lattice mismatch between the source/drain regions 402 and the epitaxial insulator layer 104. In turn, the epitaxial insulator layer 104 may apply compressive stress to the fin body portions 202a. Compressively-stressed fin body portions 202a may produce enhanced carrier mobility and increased drive current. Dopants such as boron may be incorporated into the source/drain region 402 by in-situ doping. The percentage of boron may range from approximately 1×10¹⁹ cm⁻³ to approximately 2×10²¹ cm⁻³, preferably approximately 1×10²⁰ cm⁻³ to approximately 1×10²¹ cm⁻³.

For example, for an nFET, the epitaxially grown source/drain region 402 may be made of silicon or carbon-doped silicon, where the atomic concentration of Carbon (C) may range from approximately 0.4% to approximately 3.0%, preferably from approximately 0.5% to approximately 2.5%. By including carbon in the source/drain regions 402, the source/drain regions 402 may apply tensile stress to the epitaxial insulator layer 104 due to the lattice mismatch between the source/drain regions 402 and the epitaxial insulator layer 104. In turn, the epitaxial insulator layer 104 may apply tensile stress to the fin body portions 202a. Tensily-stressed fin body portions 202a may produce enhanced carrier mobility and increased drive current. Dopants such as phosphorous or arsenic may be incorporated into the source/drain region 402 by in-situ doping. The percentage of phosphorous or arsenic may range from approximately 1×10¹⁹ cm⁻³ to approximately 2×10²¹ cm⁻³, preferably approximately 1×10²⁰ cm⁻³ to approximately 1×10²¹ cm⁻³.

By growing the source/drain regions 402 on the substantially uniform surface of the epitaxial insulator layer 104, rather than directly on the fin end portions 202b (FIG. 4), it may be possible to form more uniform source/drain regions with a consistent crystallographic orientation and doping while also preventing the formation of defects such as voids and facets.

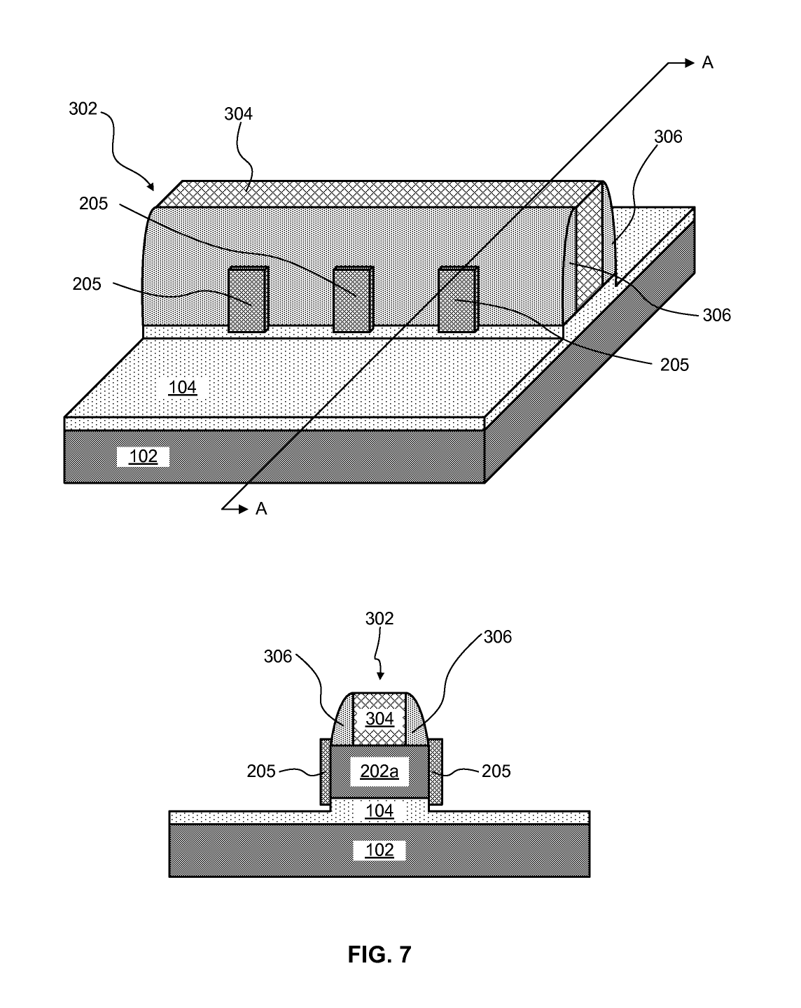

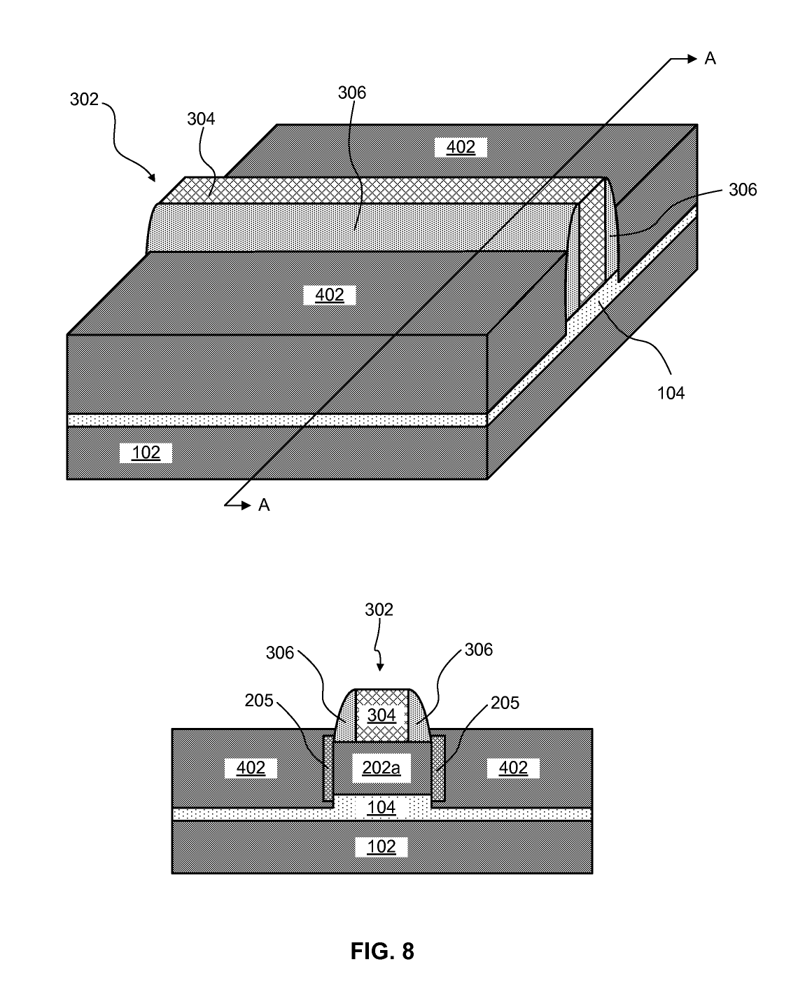

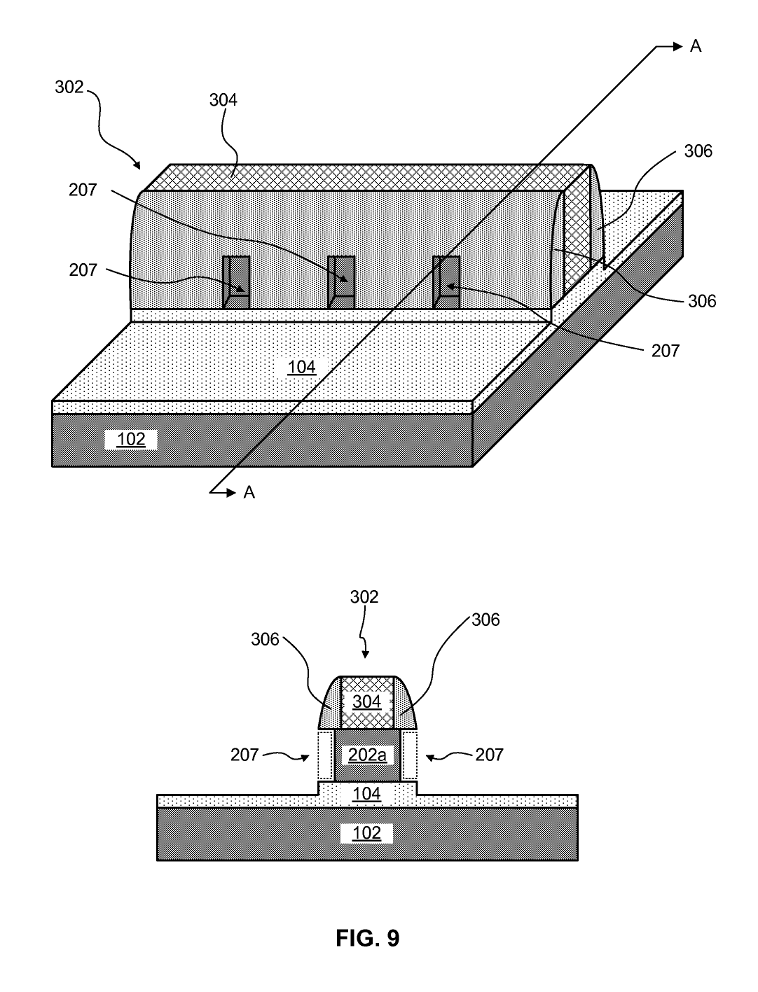

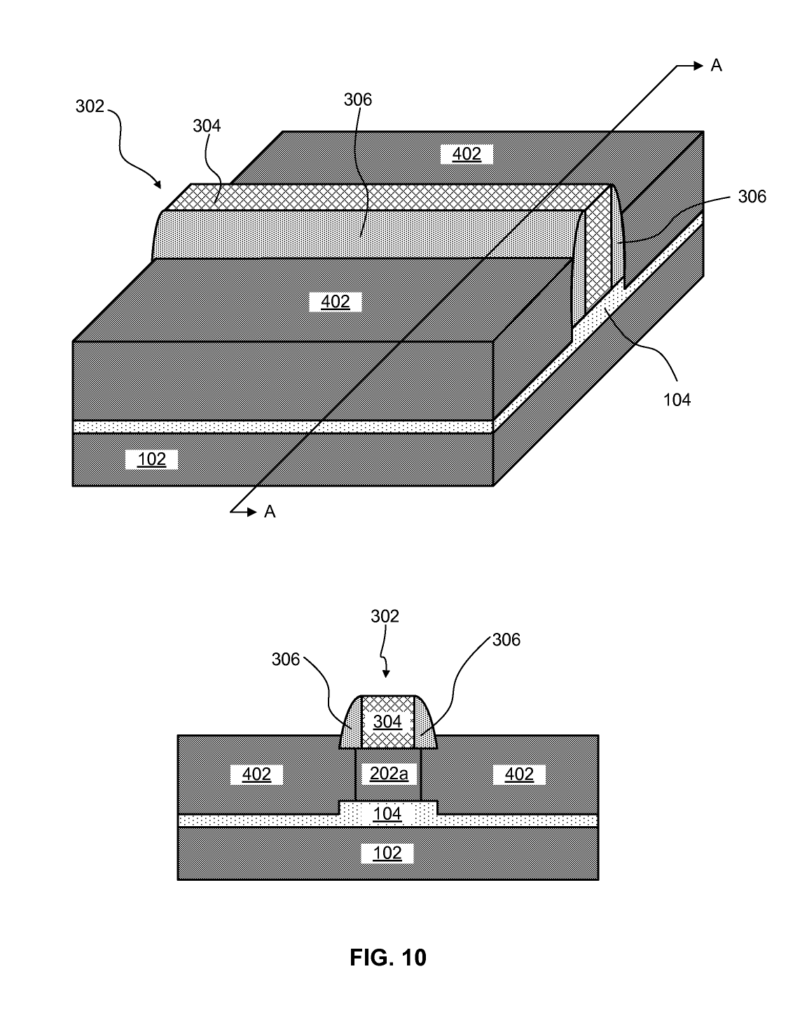

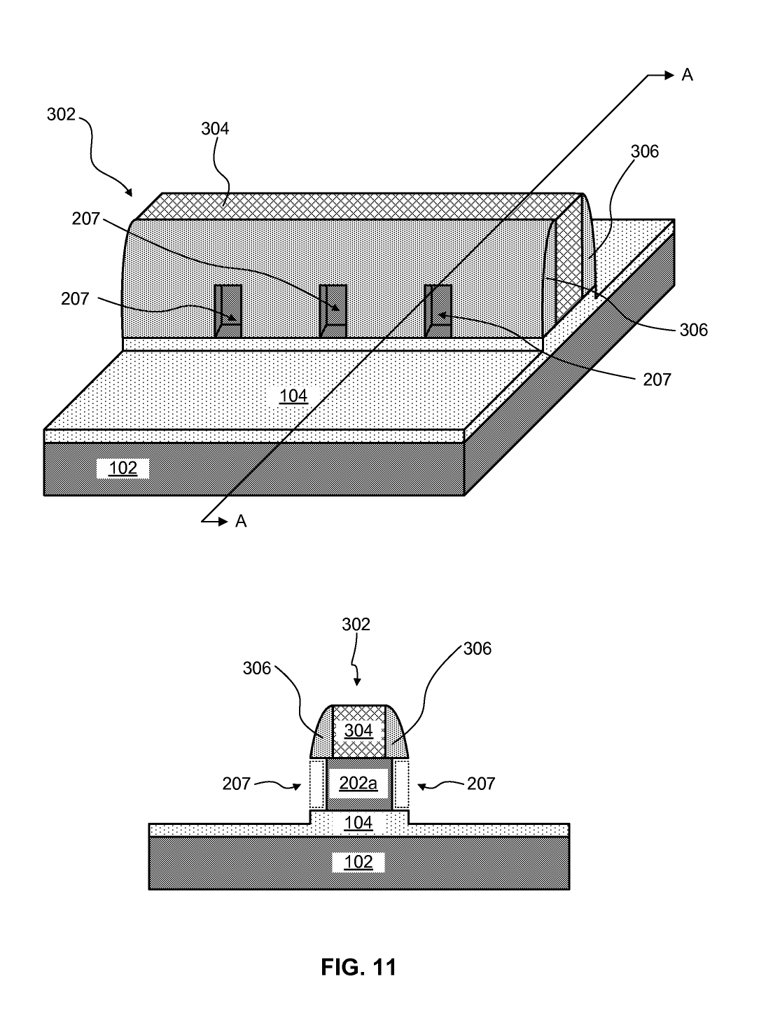

FIGS. 7-13 depict alternative embodiments to the process flow described above in conjunction with FIGS. 1-6. As depicted in FIGS. 7-8, extension regions 205 may be grown on the ends of the fin body portions 202a prior to formation of the source/drain regions 402. As depicted in FIGS. 9-10, portions of the fin body portions 202a may be removed prior to formation of the source/drain regions 402. As depicted in FIGS. 11-13, portions of the fin body portions 202a may be removed and extension regions 205 may grown on the recessed ends of the fin body portions 202a prior to formation of the source/drain regions 402. Each alternative embodiment follows the process flow described above in FIGS. 1-5 (i.e., prior to the formation of source/drain regions 402.

FIGS. 7-8 depict a method of incorporating fin extension regions 205 into the process flow described above in conjunction with FIGS. 1-6. Referring to FIG. 7, fin extension regions 205 may be formed on the exposed ends 202c of the fin body portions 202a. The fin extension regions 205 may be formed by selectively growing semiconductor material on the ends of the fin body portions 202a. The fin extension regions 205 may have a horizontal thickness of approximately 3 nm to approximately 20 nm measured from and perpendicular to the vertical plane of the spacers 306 and may extend laterally on the face of the spacers 306. Depending on the type of FET device being formed (i.e., pFET or nFET), the epitaxial source/drain regions may be made of silicon, a silicon-germanium alloy, or carbon doped silicon.

For example, for a pFET, the epitaxially grown source/drain region 402 may be made of silicon or a silicon germanium-alloy, where the atomic concentration of germanium may range from about approximately 10% to approximately 80%, preferably from approximately 20% to approximately 60%. By including germanium in the fin extension regions 205, the fin extension regions 205 may apply compressive stress to the fin body portions 202a due to the lattice mismatch between the fin extension regions 205 and the epitaxial insulator layer 104. Compressively-stressed fin body portions 202a may produce enhanced carrier mobility and increased drive current. Dopants such as boron may be incorporated into the source/drain region 402 by in-situ doping. The percentage of dopants may range from approximately 1×10¹⁹ cm⁻³ to approximately 2×10²¹ cm⁻³, preferably approximately 1×10²⁰ cm⁻³ to approximately 1×10²¹ cm⁻³.

For example, for an nFET, e epitaxially grown source/drain region 402 may be made of silicon or carbon-doped silicon, where the atomic concentration of Carbon (C) may range from approximately 0.4% to approximately 3.0%, preferably from approximately 0.5 to approximately 2.5%. By including carbon in the fin extension regions 205, the fin extension regions 205 may apply tensile stress to the fin body portions 202a due to the lattice mismatch between the fin extension regions 205 and the epitaxial insulator layer 104. Tensiley-stressed fin body portions 202a may produce enhanced carrier mobility and increased drive current. Dopants such as phosphorous or arsenic may be incorporated into the source/drain region 402 by in-situ doping. The percentage of phosphorous or arsenic may range from approximately 1×10¹⁹ cm⁻³ to approximately 2×10²¹ cm⁻³, preferably approximately 1×10²⁰ cm⁻³ to approximately 1×10²¹ cm⁻³.

Referring to FIG. 8, source/drain regions 402 may be formed by selectively growing epitaxial semiconductor layers on the epitaxial insulator layer 104, so that source/drain regions contact fin extension regions 205. The source/drain regions 402 may be formed in the same manner as described above in conjunction with FIG. 6.

The source/drain regions 402 and the fin extension regions 205 may have the same or different dopant concentration. By forming the fin extension regions 205 prior to forming source/drain regions 402, it is possible to incorporate a region of higher or lower dopant concentration near the channel region of the FET. A thermal anneal may be performed after the epitaxy growth of the extension and source/drain to activate dopants. The thermal anneal may be laser anneal, rapid thermal anneal, flash anneal, furnace anneal, or any suitable combination of those anneal techniques. In some embodiments, dopants diffuse from the source/drain regions 402 and/or the fin extension regions 205 towards the fin body portions 202a to achieve reasonable gate-to-extension overlap. In some embodiments, the extension regions have a dopant concentration ranging from 5×10¹⁸ cm⁻³ to approximately 1×10²⁰ cm⁻³ and the source/drain regions have a dopant concentration ranging from 1×10¹⁹ cm⁻³ to approximately 1×10²¹ cm⁻³ to achieve optimal device characteristics. Further, fin extension regions 205 may comprise a different material than the source/drain regions 402. For example, the fin extension regions may have a higher or lower concentration of germanium or carbon to apply more or less strain directly to the fin body portions 202a.

FIGS. 9-10 depict a method of incorporating fin recess regions 207 into the process flow described above in conjunction with FIGS. 1-6. Referring to FIG. 9, the fin recess regions 207 may be formed by etching the ends of the fin body portions 202a. The fin recess regions 207 may have a depth of approximately 0 nm to approximately 5 nm. In one embodiment, the fin recess regions 207 may have a depth of approximately 1 nm to approximately 3 nm. The fin recess regions 207 may be formed by a wet etch process capable of selectively removing material from the fin body portions 202a without substantially removing material from the surrounding spacers 306 or epitaxial insulator layer 104. In other embodiments, fin recess regions 207 may be formed by an angled anisotropic etching process capable of selectively removing material from the fin body portions 202a without substantially removing material from the surrounding spacers 306 or epitaxial insulator layer 104.

Referring to FIG. 10, source/drain regions 402 may be formed by selectively growing epitaxial semiconductor layers on the epitaxial insulator layer 104, so that source/drain regions 402 fill fin recess regions 207 and contact the fin body portions 202a. The source/drain regions 402 may be formed in the same manner as described above in conjunction with FIG. 6.

By forming the fin recess regions 207 prior to forming source/drain regions 402, the source/drain regions 402 may be located closer to the channel region of the FET. In embodiments where the source/drain regions 402 are doped, the fin recess regions 207 may therefore eliminate the need for extension implants in the fin body portions 202a to achieve a sharp junction profile and thus improve device performance.

FIGS. 11-13 depict a method of incorporating both the fin extension regions 205 described above in conjunction with FIGS. 7-8 and the fin recess regions 207 described above in conjunction with FIGS. 9-10 into the process flow described above in conjunction with FIGS. 1-6. Referring to FIG. 11, fin recess regions 207 may be formed by the same method described above in conjunction with FIG. 9. The fin recess regions 207 may have a depth of approximately 0 nm to approximately 5 nm. In one embodiment, the fin recess regions 207 may have a depth of approximately 1 nm to approximately 3 nm.

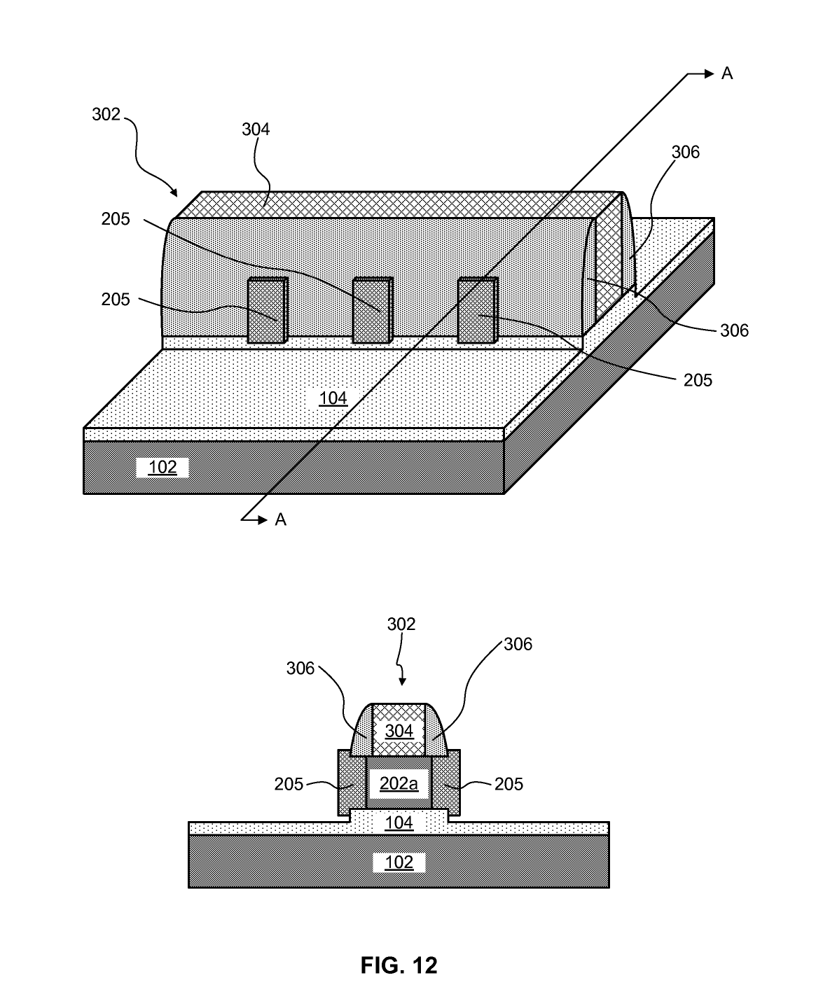

Referring to FIG. 12, fin extension regions 205 may be formed on the end of the fin body portions 202a in the fin recess regions 207 using the same epitaxial growth processes described above in conjunction with FIG. 9. In some embodiments, fin extension regions may not extend beyond the fin recess regions 207. In other embodiments, the fin extension regions 205 may have a horizontal thickness of approximately 2 nm to approximately 20 nm, and preferably approximately 5 to approximately 10 nm measured from and perpendicular to the vertical plane of the spacers 306 and may extend laterally on the face of the spacers 306.

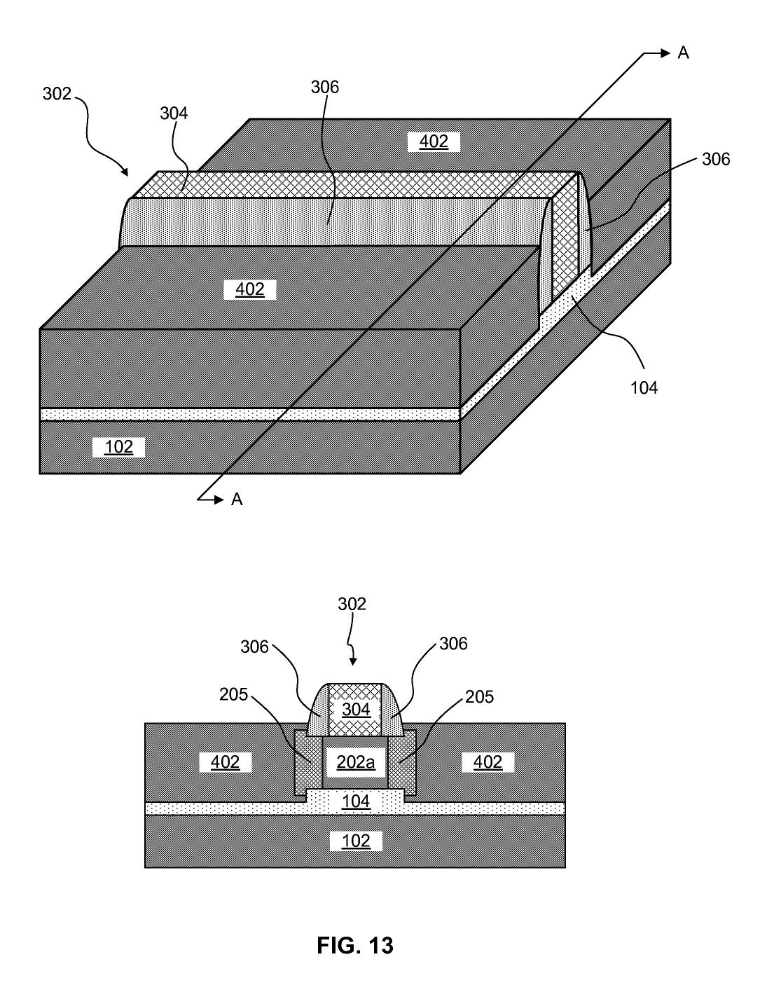

Referring to FIG. 13, source/drain regions 402 may be formed by selectively growing epitaxial semiconductor layers on the epitaxial insulator layer 104, so that source/drain regions contact fin extension regions 205. The source/drain regions 402 may be formed in the same manner as described above in conjunction with FIG. 6.

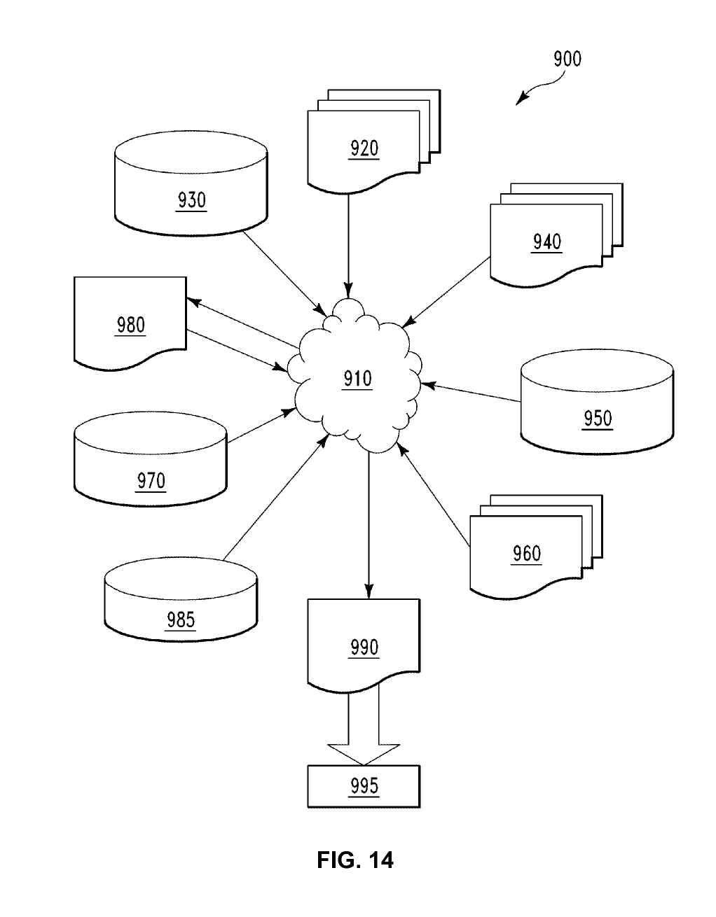

Referring to FIG. 14, shows a block diagram of an exemplary design flow 900 used for example, in semiconductor IC logic design, simulation, test, layout, and manufacture. Design flow 900 includes processes and mechanisms for processing design structures or devices to generate logically or otherwise functionally equivalent representations of the design structures and/or devices described above and shown in FIGS. 6, 8, 10, and 13. The design structure processed and/or generated by design flow 900 may be encoded on machine-readable transmission or storage media to include data and/or instructions that when executed or otherwise processed on a data processing system generate a logically, structurally, mechanically, or otherwise functionally equivalent representation of hardware components, circuits, devices, or systems.

Design flow 900 may vary depending on the type of representation being designed. For example, a design flow 900 for building an application specific IC (ASIC) may differ from a design flow 900 for designing a standard component or from a design flow 900 for instantiating the design into a programmable array, for example a programmable gate array (PGA) or a field programmable gate array (FPGA) offered by Altera® Inc. or Xilinx® Inc.

FIG. 14 illustrates multiple such design structures including an input design structure 920 that is preferably processed by a design process 910. In one embodiment, the design structure 920 comprises design data used in a design process and comprising information describing one or more embodiments of the invention with respect to the structures as shown in FIGS. 6, 8, 10, and 13. The design data in the form of schematics or HDL, a hardware-description language (e.g., Verilog, VHDL, C, etc.) may be embodied on one or more machine readable media. For example, design structure 920 may be a text file, numerical data or a graphical representation of the one or more embodiments of the invention, as shown in FIGS. 6, 8, 10, and 13. Design structure 920 may be a logical simulation design structure generated and processed by design process 910 to produce a logically equivalent functional representation of a hardware device. Design structure 920 may also or alternatively comprise data and/or program instructions that when processed by design process 910, generate a functional representation of the physical structure of a hardware device. Whether representing functional and/or structural design features, design structure 920 may be generated using electronic computer-aided design (ECAD) such as implemented by a core developer/designer. When encoded on a machine-readable data transmission, gate array, or storage medium, design structure 920 may be accessed and processed by one or more hardware and/or software modules within design process 910 to simulate or otherwise functionally represent an electronic component, circuit, electronic or logic module, apparatus, device, or system such as those shown in FIGS. 6, 8, 10, and 13. As such, design structure 920 may comprise files or other data structures including human and/or machine-readable source code, compiled structures, and computer-executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 910 preferably employs and incorporates hardware and/or software modules for synthesizing, translating, or otherwise processing a design/simulation functional equivalent of the components, circuits, devices, or logic structures shown in FIGS. 6, 8, 10, and 13 to generate a netlist 980 which may contain a design structure such as design structure 920. Netlist 980 may comprise, for example, compiled or otherwise processed data structures representing a list of wires, discrete components, logic gates, control circuits, I/O devices, models, etc. that describes the connections to other elements and circuits in an integrated circuit design. Netlist 980 may be synthesized using an iterative process in which netlist 980 is resynthesized one or more times depending on design specifications and parameters for the device. As with other design structure types described herein, netlist 980 may be recorded on a machine-readable data storage medium or programmed into a programmable gate array. The medium may be a non-volatile storage medium such as a magnetic or optical disk drive, a programmable gate array, a compact flash, or other flash memory. Additionally, or in the alternative, the medium may be a system or cache memory, buffer space, or electrically or optically conductive devices and materials on which data packets may be transmitted and intermediately stored via the Internet, or other networking suitable means.

Design process 910 may include hardware and software modules for processing a variety of input data structure types including netlist 980. Such data structure types may reside, for example, within library elements 930 and include a set of commonly used elements, circuits, and devices, including models, layouts, and symbolic representations, for a given manufacturing technology (e.g., different technology nodes, 20, 32 nm, 45 nm, 90 nm, etc.). The data structure types may further include design specifications 940, characterization data 950, verification data 960, design rules 970, and test data files 985 which may include input test patterns, output test results, and other testing information. Design process 910 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 910 without deviating from the scope and spirit of the invention. Design process 910 may also include modules for performing standard circuit design processes such as timing analysis, verification, design rule checking, place and route operations, etc.

Design process 910 employs and incorporates logic and physical design tools such as HDL compilers and simulation model build tools to process design structure 920 together with some or all of the depicted supporting data structures along with any additional mechanical design or data (if applicable), to generate a second design structure 990 comprising second design data embodied on a storage medium in a data format used for the exchange of layout data of integrated circuits and/or symbolic data format (e.g. information stored in a GDSII (GDS2), GL1, OASIS, map files, or any other suitable format for storing such design structures). In one embodiment, the second design data resides on a storage medium or programmable gate array in a data format used for the exchange of data of mechanical devices and structures (e.g. information stored in a IGES, DXF, Parasolid XT, JT, DRG, or any other suitable format for storing or rendering such mechanical design structures). Similar to design structure 920, design structure 990 preferably comprises one or more files, data structures, or other computer-encoded data or instructions that reside on transmission or data storage media and that when processed by an ECAD system generate a logically or otherwise functionally equivalent form of one or more of the embodiments of the invention shown in FIG. 6. In one embodiment, design structure 990 may comprise a compiled, executable HDL simulation model that functionally simulates the devices shown in FIGS. 6, 8, 10, and 13.

Design structure 990 may also employ a data format used for the exchange of layout data of integrated circuits and/or symbolic data format (e.g. information stored in a GDSII (GDS2), GL1, OASIS, map files, or any other suitable format for storing such design data structures).

Design structure 990 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce the device or structure as described above and shown in FIG. 6. Design structure 990 may then proceed to a stage 995 where, for example, design structure 990: proceeds to tape-out, is released to manufacturing, is released to a mask house, is sent to another design house, is sent back to the customer, etc.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiment, the practical application or technical improvement over technologies found in the marketplace, or to enable other of ordinary skill in the art to understand the embodiments disclosed herein. It is therefore intended that the present invention not be limited to the exact forms and details described and illustrated but fall within the scope of the appended claims.

What is claimed is:

1. A semiconductor structure comprising:
an epitaxial insulator layer above a base substrate;
a gate structure above the an epitaxial insulator layer;
a semiconductor fin below the gate structure, wherein an end of the semiconductor fin is not covered by the gate structure; and
an epitaxial source/drain region on the epitaxial insulator layer adjacent to the end of the semiconductor fin.

2. The structure of claim 1, wherein the epitaxial insulator layer comprises a single-crystal layer of a material selected from the group comprising scandium oxide, cadmium oxide, yttrium oxide, scandium oxide, lanthanum oxide, praseodymium oxide, thorium oxide, actinium oxide, gadolinium oxide, strontium titanate, and barium titanate.

3. The structure of claim 1, wherein the epitaxial source/drain region comprises epitaxial silicon, epitaxial silicon-germanium, or epitaxial carbon-doped silicon.

4. The structure of claim 1, wherein the epitaxial insulator layer is thinner beneath the epitaxial source/drain region than beneath the gate structure.

5. The structure of claim 1, further comprising a fin extension region on the end of the semiconductor fin between the end of the semiconductor fin and the epitaxial source/drain region.

6. The structure of claim 1, wherein the end of the semiconductor fin is recessed beneath the gate structure.

7. A method of forming a semiconductor structure:
forming a semiconductor fin on an epitaxial insulator layer;
forming a gate structure over a body portion of the semiconductor fin, said gate structure including a gate electrode and a spacer on a sidewall of the gate electrode, wherein an end portion of the semiconductor fin remains not covered by the gate structure;
removing the end portion of the semiconductor fin; and
forming an epitaxial source/drain region on the epitaxial insulator layer and in contact with the body portion of the semiconductor fin.

8. The method of claim 7, wherein the epitaxial insulator layer comprises a single-crystal layer of a material selected from the group comprising scandium oxide, cadmium oxide, yttrium oxide, scandium oxide, lanthanum oxide, praseodymium oxide, thorium oxide, actinium oxide, gadolinium oxide, strontium titanate, and barium titanate.

9. The method of claim 7, further comprising thinning the epitaxial insulator layer prior to forming an epitaxial source/drain region on the epitaxial insulator layer.

10. The method of claim 9, where in the epitaxial insulator layer is thinned outside the gate structure prior to forming the epitaxial source/drain region.

11. The method of claim 7, further comprising forming an extension region on the body portion of the semiconductor fin prior to forming an epitaxial source/drain region on the epitaxial insulator layer.

12. The method of claim 11, wherein forming the extension region on the body portion of the semiconductor fin comprises growing epitaxial silicon, silicon-germanium, or carbon-doped silicon region on the body portion of the semiconductor fin

13. The method of claim 7, further comprising recessing the body portion of the semiconductor fin beneath the spacer prior to forming an epitaxial source/drain region on the epitaxial insulator layer.

14. The method of claim 13, wherein the body portion of the semiconductor fin is recessed by a wet etching process.

15. The method of claim 7, further comprising:
recessing the body portion of the semiconductor fin;
forming an extension region on the body portion of the semiconductor fin prior to forming an epitaxial source/drain region on the epitaxial insulator layer.

16. A design structure tangibly embodied in a machine readable medium for designing, manufacturing, or testing an integrated circuit, the design structure comprising:
an epitaxial insulator layer above a base substrate;
a gate structure above the an epitaxial insulator layer;
a semiconductor fin below the gate structure, wherein an end of the semiconductor fin is not covered by the gate structure; and
an epitaxial source/drain region on the epitaxial insulator layer adjacent to the end of the semiconductor fin.

17. The structure of claim 16, wherein the epitaxial insulator layer is thinner beneath the epitaxial source/drain region than beneath the gate structure.

18. The structure of claim 16, further comprising a fin extension region on the end of the semiconductor fin between the end of the semiconductor fin and the epitaxial source/drain region.

19. The structure of claim 16, wherein the semiconductor fin is recessed beneath the gate structure.

20. The structure of claim 16, wherein:
the epitaxial insulator layer comprises a single-crystal layer of a material selected from the group comprising scandium oxide, cadmium oxide, yttrium oxide, scandium oxide, lanthanum oxide, praseodymium oxide, thorium oxide, actinium oxide, gadolinium oxide, strontium titanate, and barium titanate; and
the epitaxial source/drain region comprises epitaxial silicon, epitaxial silicon-germanium, or epitaxial carbon-doped silicon.
